(19) United States
(12) Patent Application Publication
(10) Pub. No.: US 2008/0195901 A1
(43) Pub. Date: Aug. 14, 2008

(54) OP-CODE BASED BUILT-IN-SELF-TEST

(75) Inventors: Yosef Solt, Misgav (IL); Eitan Joshua, Kiryat Tivon (IL)

Correspondence Address: BRINKS HOFER GILSON & LIONE/MARVELL, P.O. BOX 10395, CHICAGO, IL, 60610, US

(73) Assignee: Marvell Semiconductor Israel Ltd., Yokneam, IL (US)

(21) Appl. No.: 11/969,022

(22) Filed: Jan. 3, 2008

Related U.S. Application Data
(60) Provisional application No. 60/889,476, filed on Feb. 12, 2007.

(51) Int. Cl. G11C 29/12; G06F 11/26; G06F 11/22

(52) U.S. Cl. 714/718; 714/733; 714/E11.169; 714/E11.148

(57) ABSTRACT

A built-in-self-test (BIST) system for testing a memory that includes a scheduler module that generates a first test algorithm based on a set of operational codes. Each operational code defines a test operation to be performed by the first test algorithm on the memory. The BIST system also includes an execution module that applies the first test algorithm to the memory.

### RELATED APPLICATION

This application claims the benefit of U.S. Provisional Application No. 60/889,476, filed on Feb. 12, 2007, which is incorporated herein by reference.

### BACKGROUND

1. Technical Field

The present disclosure relates to built-in-self-tests (BISTs) and, more particularly, to efficient and flexible memory BISTs (MBISTs) for testing memories.

2. Related Art

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Integrated circuits (ICs) are often designed as system on chip (SOC) circuits that include various interfaces, firmware, processors, and/or embedded memories. The embedded memories are increasingly accounting for a greater percentage of the area of the SOC circuit. Additionally, as fabrication technologies evolve, the circuit density of embedded memories is rapidly increasing. As a result, the embedded memories require more efficient and cost effective testing schemes to identify potential defects.

One testing alternative involves the use of costly automated test equipment. Automated test equipment often requires the use of complex test algorithms but provides the flexibility to apply later-developed test algorithms to detect defects associated with newer technology. Recent testing methods have turned to built-in-self-tests (BISTs) which allow testing “at speed” of the embedded memories. However, BISTs generally support significantly fewer tests algorithms and are limited to those test algorithms hard-wired into circuitry during the manufacturing process.

### BRIEF SUMMARY

The present invention is defined by the following claims, and nothing in this section should be taken as a limitation on those claims.

By way of introduction, the preferred embodiments below provide a built-in-self-test (BIST) system for memory that includes a scheduler module that generates a first test algorithm based on a set of operational codes. Each operational code defines a test operation to be performed by the first test algorithm on the memory. The BIST system also includes an execution module that applies the first test algorithm to the memory.

A BIST system for testing a memory that includes scheduler means for generating a first test algorithm based on a set of operational codes, wherein each operational code defines a test operation performed by the first test algorithm on the memory and execution means for applying the first test algorithm to the memory.

In other features, the BIST system further comprises an external device that defines at least one of the set of operational codes to be performed by the first test algorithm and that defines a sequence of performing the set of operational codes. The set of operational codes is stored internal to a device that includes the memory. The scheduler means generates the first test algorithm when the BIST system receives a trigger command. The scheduler means retrieves the set operational codes from an internal memory of the BIST system. The execution means applies the first test algorithm at an operating speed of the memory.

In other features, the scheduler means generates a second test algorithm that is different from the first test algorithm when the external device modifies one of the composition of the set of operational codes and the sequence of the operational codes relative to the first test algorithm. The scheduler means generates a second test algorithm when an external device transmits to the scheduler module another operational code that is different from the set of operational codes in the first test algorithm.

In other features, the scheduler means receives the set of operational codes from an external device. The external device includes automated test equipment.

In other features, the scheduler means transmits a pass signal when the test algorithm fails to generate an error and transmits a fail signal when the test algorithm generates an error. The memory includes memory external to the BIST system.

A computer-readable storage medium storing a computer program that includes instructions for causing a processor to generate a test algorithm based on the set of operational codes, wherein each operational code corresponds to one of a plurality of operations performed by the test algorithm and to apply the test algorithm to the memory.

In other features, the computer-readable storage medium further comprises instructions for causing the processor to generate the test algorithm based on receiving a trigger command. The computer-readable storage medium further comprises instructions for causing the processor to retrieve the set of operational codes from an internal memory.

In other features, the computer-readable storage medium further comprises instructions for causing the processor to apply the test algorithm at an operating speed of the memory. The computer-readable storage medium further comprises instructions for causing the processor to generate a second test algorithm by modifying one operational code of the set of operational codes. The computer-readable storage medium further comprises instructions for causing the processor to generate a second test algorithm based on receiving another operational code different from the set of operational codes.

In other features, the computer-readable storage medium further comprises instructions for causing the processor to receive the set of operational codes from an external device.

In other features, the external device includes automated test equipment. The computer-readable storage medium further comprises instructions for causing the processor to apply the test algorithm at an operating speed of the memory.

In other features, the computer-readable storage medium further comprises instructions for causing the processor to generate a second test algorithm when the external device modifies one operational code of the set of operational codes. The computer-readable storage medium further comprises instructions for causing the processor to generate a second test algorithm when the external device transmits another operational code different from the set of operational codes. The computer-readable storage medium further comprises instructions for causing the processor to transmit a pass signal when the test algorithm fails to generate an error and transmit a fail signal when the test algorithm generates an error.

Other systems, methods, and features of the invention will be, or will become, apparent to one with skill in the art upon examination of the following figures and detailed description. It is intended that all such additional systems, methods, features and advantages be included within this description, be within the scope of the invention, and be protected by the following claims.

The preferred embodiments will now be described with reference to the attached drawings.

### BRIEF DESCRIPTION OF THE DRAWINGS

FIG. 1 is a functional block diagram of a test environment for various types of memories according to the present disclosure;

FIG. 2 is a functional block diagram of an exemplary built-in-self-test (BIST) controller module of a BIST system according to the present disclosure;

FIG. 3(a) is a block diagram of a first exemplary implementation of a MBIST module of a BIST system according to the present disclosure;

FIG. 3(b) is a block diagram of a first exemplary implementation of a MBIST module of the BIST system according to the present disclosure;

FIG. 4(a) is a flow diagram illustrating steps of executing an operation of the first exemplary implementation of the BIST system according to the present disclosure;

FIG. 4(b) is a flow diagram illustrating steps of executing an operation of the second exemplary implementation of the BIST system according to the present disclosure;

FIG. 5(a) is a functional block diagram of a hard disk drive;

FIG. 5(b) is a functional block diagram of a digital versatile disk (DVD);

FIG. 5(c) is a functional block diagram of a high definition television;

FIG. 5(d) is a functional block diagram of a vehicle control system;

FIG. 5(e) is a functional block diagram of a cellular phone;

FIG. 5(f) is a functional block diagram of a set top box;

FIG. 5(g) is a functional block diagram of a media player; and

FIG. 5(h) is a functional block diagram of a VoIP phone.

### DETAILED DESCRIPTION OF THE PRESENTLY PREFERRED EMBODIMENTS

The disclosure can be better understood with reference to the following drawings and description. The components in the figures are not necessarily to scale, emphasis instead being placed upon illustrating teaching principles of the invention. Moreover, in the figures, like referenced numerals designate corresponding parts or elements throughout the different views. The following description is merely an example and is in no way intended to limit the disclosure, its application, or uses. As used herein, the term module refers to an Application Specific Integrated Circuit (ASIC), an electronic circuit, a processor (shared, dedicated, or group) and memory that execute one or more software or firmware programs, a combinational logic circuit, and/or other suitable components that provide the described functionality. As used herein, the phrase at least one of A, B, and C should be construed to mean a logical (A or B or C), using a non-exclusive logical or. It should be understood that operations within a method may be executed in different order without altering the principles of the present disclosure.

By way of introduction, the embodiments described herein are related to memories of various integrated circuits (ICs). More particularly, the present disclosure describes a built-in-self-test (BIST) system that enables testing a memory “at speed” (i.e., at an operating speed of the target memory) and provides enhanced flexibility with regards to modifying existing test algorithms of the memory as well as upgrading the test algorithms after the initial design of the BIST system.

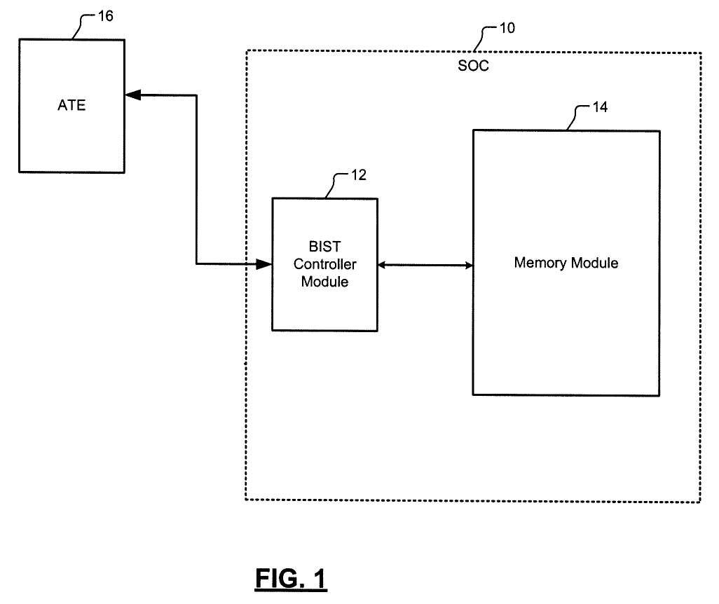

Referring now to FIG. 1, an example of a system on chip (SOC) circuit 10 that implements the BIST system of the present disclosure is shown to include a BIST controller module 12 and a memory module 14. The SOC 14 may also include, but is not limited to, microcontrollers, microprocessors, digital signal processing cores, an oscillator, phase-locked loop (PLL), peripherals, interfaces, voltage regulators, and/or power management circuits. Additionally, although a single memory module 14 is depicted, it is appreciated that the SOC circuit 10 may include additional memory modules 14. The memory module 14 may include embedded memory such as dynamic random access memory (DRAM), static random access memory (SRAM), cache, register files, Flash, and/or various types of content-addressable memory such as ternary CAM (TCAM).

The BIST controller module 12 implements the BIST system of the present disclosure and is shown to communicate with external automated test equipment (ATE) 16 and the memory module 14. Typically, an ATE is utilized to test electronic devices such as ICs (e.g., the SOC circuit 10) for defects that may arise during production. An ATE generally interfaces with an automated placement tool commonly referred to as a “handler” that serves to physically place a memory under test.

In one example, the ATE 16 triggers the BIST controller module 12 to initiate testing of the memory module 14 by applying test algorithms to the memory module 14 based on input (e.g., operational codes) received from the ATE 16. In a second implementation, the BIST controller module 12 tests the memory module 14 based on operational codes (op-codes) stored in internal memory of the BIST controller module 12. An op-code represents a portion of a machine language instruction that defines an operation that is scheduled to be executed. Typically, a machine language instruction includes an op-code and one or more operands. Operands may include, but are not limited to, registers, input/output ports, stack values, and/or memory. The present disclosure contemplates the operands of various op-codes to include memory cells (i.e., addressable elements) of the memory module 14. Op-codes may define, for example, a read or write operation, and maybe combined and/or sequenced in a selected manner to form a test algorithm. As such, several test algorithms may be generated based on various combinations of a specified set of stored op-codes, thereby conserving storage space by eliminating the need to store an entire test algorithm in internal memory of a chip or transmitting an entire test algorithm from an external device such as an ATE.

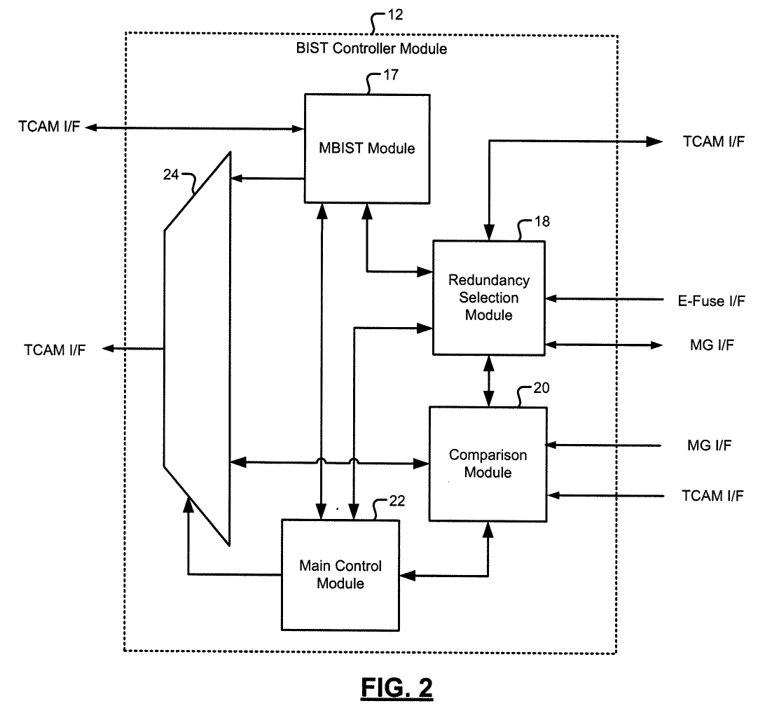

Referring now to FIG. 2, an example of a BIST controller module 12 that implements the BIST system of the present disclosure is shown to include an MBIST module 17, a redundancy selection module 18, a comparison module 20, a main control module 22, and a multiplexer module 24. Although the BIST system seen in FIG. 2 is implemented within a TCAM environment, the present disclosure anticipates utilizing the BIST system of the present disclosure in various other memories (e.g., memory external to the BIST system). In the present implementation, the MBIST module 17 and/or the comparison module 20 may implement the BIST system of the present disclosure. However, for the sake of simplicity and brevity, the present disclosure will discuss the operation of the BIST system with reference to the MBIST module 17 though those skilled in the art will appreciate that the comparison module 20 may implement the BIST system in similar fashion.

The main control module 22 communicates with the MBIST module 17, the redundancy selection module 18, the comparison module 20, and the multiplexer module 24. The main control module 22 serves as the primary state machine of the BIST controller module 12 and synchronizes various test algorithms executed on the memory module 14 such as comparison test algorithms and memory self-test algorithms. In the present implementation, the main control module 22 may selectively initiate comparison test algorithms and/or the memory self test algorithms applied to the memory module 14 based on input received from the ATE 16 or a pre-established test sequence. For example, the main control module 22 triggers one or more memory self-test algorithms and receives a “pass” signal (i.e., a signal indicating the memory self-test algorithm(s) has executed without generating errors) prior to triggering one or more comparison test algorithms. Memory self-test algorithms are defined by a combination of op-codes that are scheduled to be implemented based on various instruction sets. Additionally, the BIST main module 22 operates to control the output of the multiplexer module 24.

The comparison module 20 controls/manages the comparison test algorithms applied to the memory module 14. More specifically, the comparison test algorithms apply write/read/comparison operations (i.e., various op-codes) on cells of the memory module 14 utilizing “configurable” commands to compare received data to internal data lines of the memory module 14. The configurable commands enable a user (not shown) of the BIST system to determine how to initialize cells of the memory module 14, the data backgrounds utilized during a comparison test algorithm, and the types of output (i.e., “hit result”) to expect upon completion of a comparison test algorithm. The configurable commands are based in-part on selectively sequenced op-codes stored within a plurality of registers (not shown) of the comparison module 20. In the present implementation, the BIST system of the present disclosure may utilize predetermined op-codes and also allocates register space in memory for dynamic user-defined algorithms. As mentioned previously, each distinct comparison test algorithm applied to the memory module 14 is comprised of a distinct combination of op-codes and may indicate an order, or sequence, for applying the op-codes. In other words, the composition (i.e., the sequencing of op-codes and the cells of memory module 14, or target, to be operated upon) of each comparison test algorithm may be programmable.

The redundancy selection module 18 communicates with the MBIST module 17, the comparison module 20, and the main control module 22. The redundancy selection module 18 allocates row redundancy for the BIST controller module 12 based on requests received from the comparison module 20 and/or the MBIST module 17. The multiplexer module 24 selectively outputs data from one of the comparison module 20 and the MBIST module 17 based on input received from the main control module 22.

As noted above, the MBIST module 17 may implement the MBIST system. The MBIST module 17 controls/manages the memory self-test algorithms applied to the memory module 14. The operation of the MBIST module 17 will be described in further detail below. In the present implementation, the comparison test algorithms and the memory self test algorithms typically perform a full pass through the entire memory module 14 (i.e., testing each cell of the memory module 14), although the present disclosure anticipates specifying a range of addresses of the memory module 14 to be tested.

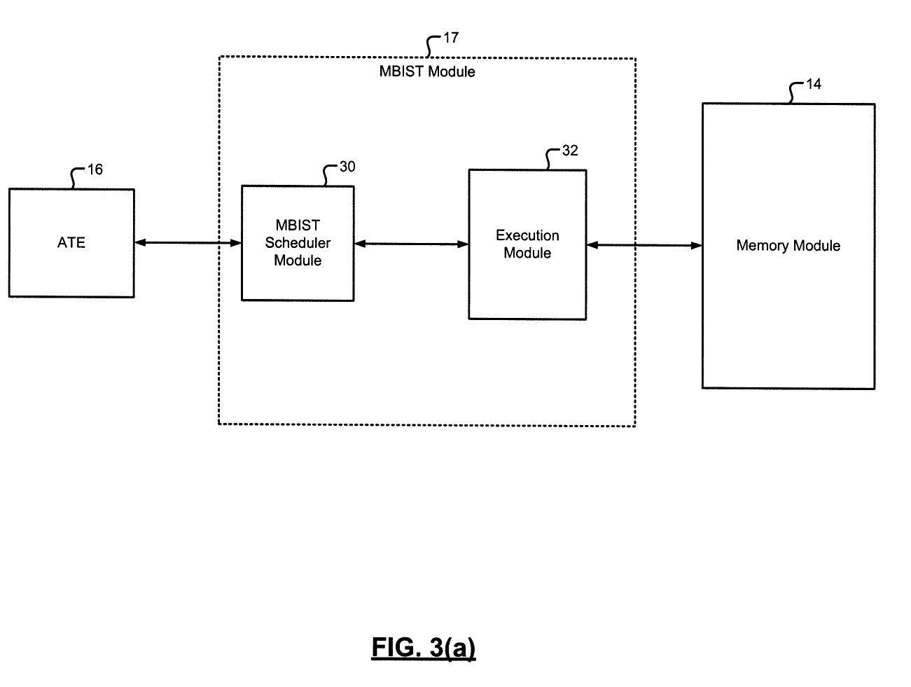

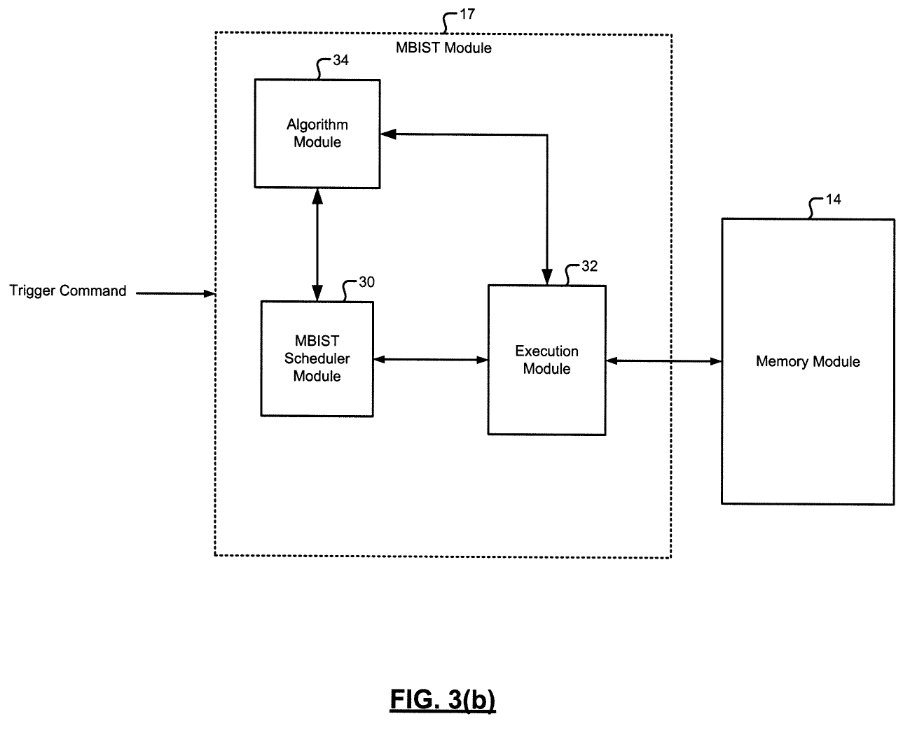

Referring now to FIG. 3(a), a first implementation of the MBIST module 17 is shown to include an MBIST scheduler module 30 and an execution module 32. In the present implementation, the MBIST scheduler module 30 receives op-codes transmitted from the ATE 16. The ATE 16 additionally provides the composition (i.e., the scheduling of the transmitted op-codes and the cells of memory module 14 to be operated upon) of each memory self-test algorithm. The MBIST scheduler module 30 sequences the received op-codes based on an instruction received from the ATE 16 to generate and initiate a particular memory self-test algorithm. The execution module 32 receives and “runs” (i.e., applies) the memory self-test algorithm on the memory module 14. The execution module 32 signals the completion of the memory self-test algorithm to the MBIST scheduler module 30. In various embodiments, the op-codes maybe hardwired on the SOC 10. The MBIST scheduler then communicates whether the memory module 14 passed or failed the memory self-test algorithm to the ATE 16.

As previously noted, each op-code represents a portion of a machine language instruction that indicates the operation that is scheduled to be executed (i.e., each op-code represents an operation). The MBIST module 17 utilizes a set of op-codes to perform each memory self-test algorithm. The memory self-test algorithms include, but are not limited to, March C+, March C, March C−, March LR, and various checkerboard memory self-test algorithms. As noted previously, each op-code equates to a modular building structure, or fundamental operation, of a memory self-test algorithm. Therefore, each memory self-test algorithm is defined by a particular set of selectively sequenced op-codes that are applied to selected cells (i.e., a target) of memory module 14. As such, the BIST system enables the MBIST module 17 to apply a memory self-test algorithm to the memory module 14 based solely on op-codes that may be received from the ATE 16. Alternatively, the op-codes may be hardwired on the SOC 10 in which case the ATE 16 transmits a programmable instruction set indicating the set of op-codes to be applied, sequencing instructions and the targeted cells of memory module 14. Since the ATE 16 may transmit several distinct combinations of op-codes, the MBIST module 17 of the present disclosure can provide substantial flexibility with regards to the selection of memory self-test algorithms available for use. Additionally, the MBIST module 17 allows for the memory module 14 to be tested at its own operating speed.

Furthermore, several memory self-test algorithms may share common op-codes (i.e., common set of operations). For example, the March test algorithms (e.g., March C+, March C, March C−, and March LR) that typically test for simple faults and realistic linked faults, generally each include performing common read and/or write accesses to various cells of the memory module 14 as well as potentially sharing a common marching scheme (e.g., ascending or descending) through the memory module 14. Additionally, common data backgrounds may be utilized during the application of each of the March test algorithms. It is noted that the March test algorithms may share other commonalities such as the number of read operations of a particular cell and/or the increment/decrement steps used during a marching scheme and the disclosure is not limited by the present examples.

Since several memory self-test algorithms may share common op-codes, the MBIST system of the present disclosure can readily apply a “new” memory self-test algorithm or modify an existing memory self-test algorithm (i.e., execute a memory self-test algorithm different from the selection of memory self-test algorithms generated by previously transmitted op-codes) by receiving a “new” or modified op-code from the ATE 16.

Referring now to FIGS. 3(a) and 3(b), a second implementation of the MBIST module 17 is shown. In FIG. 3(b) the MBIST module 17 further includes an algorithm module 34 that comprises at least one algorithm table that stores the plurality of op-codes utilized while testing the memory module 14. Upon receiving an external trigger command from an external (i.e., external to the SOC 10) management device (not shown), the MBIST scheduler module 30 retrieves a plurality of op-codes from the op-code table to generate the selected memory self-test algorithm. The execution module 32 then applies the memory self-test algorithm to the memory module 14.

Conventional BIST controllers such as non-programmable controllers require entire pre-established algorithms to be hard-wired in the BIST controller therefore allowing for minimal modifications to the pre-established algorithms after production of the chip (i.e., providing minimal testing flexibility). On the other hand, programmable BIST controllers provide increased flexibility over non-programmable controllers but also demand considerable storage capacity in memory.

In the present implementation, the op-codes are stored internally (i.e., the op-codes are hardwired) within the BIST controller module 12. As discussed previously, each memory self-test algorithm is defined by a particular set of op-codes (i.e., a plurality of op-codes are sequenced to generate a memory self-test algorithm). Each memory self-test algorithm is then generated based on instructions received from the ATE 16 that indicate which internally stored op-codes are to be implemented. As a result, storage space of the SOC 10 is conserved since a set of op-codes requires less storage space within memory of the BIST controller module 12 than an entire memory self-test algorithm. Additionally, the BIST system of the present implementation provides increased flexibility by enabling dynamic sequencing and scheduling of memory self-test algorithms based on various op-codes retrieved from the algorithm module 34.

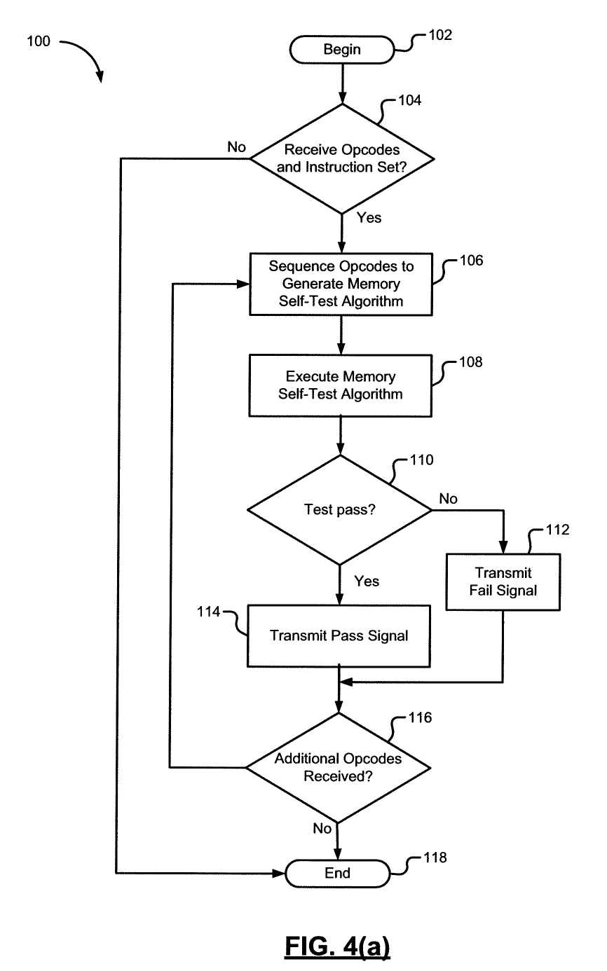

Referring now to FIG. 4(a), a method 100 for operating a first implementation of the BIST system is shown in more detail. The method 100 begins at step 102. In step 104, the MBIST scheduler module 30 determines whether a set of op-codes and an instruction set has been received. As noted previously, the op-codes maybe hardwired on the SOC 10 or received from the ATE 16. If the MBIST scheduler module 30 has not received a set of op-codes and an instruction set, the method 100 proceeds to step 118. If the MBIST scheduler module 30 receives a set of op-codes and an instruction set, the method 100 proceeds to step 106.

In step 106, the MBIST scheduler module 30 sequences the op-codes based on the instruction set to generate a selected memory self-test algorithm based on the op-codes. In step 108, the execution module 32 executes (i.e. applies) the memory self-test algorithm to the memory module 14. In step 110, the MBIST scheduler module 30 determines whether the memory module 14 “passed” the memory self-test algorithm. If the memory module 14 does not pass the memory self-test algorithm, the method 100 proceeds to step 112. If the memory module 14 passes the memory self-test algorithm, the method 100 proceeds to step 114.

In step 112, the MBIST scheduler module 30 transmits a fail signal to the ATE 16. In step 114, the MBIST scheduler module 30 transmits a pass signal to the ATE 16. In step 116, the MBIST scheduler module 30 determines whether additional op-codes and instruction sets have been received. If the MBIST schedule module 30 has received additional op-codes and instruction sets, the method 100 returns to step 106. If the MBIST scheduler module 30 does not receive additional op-codes and additional instruction sets, the method 100 proceeds to step 118 where the method 100 ends.

Referring now to FIG. 4(b), a method 200 for operating the second implementation of the BIST system is shown in more detail. The method 200 begins at step 202. In step 204, the MBIST module 17 determines whether a trigger command has been received. If the MBIST module 17 has not received a trigger command, the method 200 proceeds to step 222 where the method 200 ends. If the MBIST module 17 has received a trigger command, the method 200 proceeds to step 206.

In step 206, the MBIST scheduler module 30 identifies a set of op-codes corresponding to a desired memory self-test algorithm. In step 208, the MBIST scheduler module 30 retrieves the set of op-codes from the algorithm module 34. In step 210, the MBIST scheduler module 30 sequences the set of op-codes to generate the selected memory self-test algorithm based on the op-codes. In step 212, the execution module 32 executes (i.e. applies) the memory self-test algorithm to the memory module 14. In step 214, the MBIST scheduler module 30 determines whether the memory module 14 “passed” the memory self-test algorithm. If the memory module 14 does not pass the memory self-test algorithm, the method 200 proceeds to step 216. If the memory module 14 passes the memory self-test algorithm, the method 200 proceeds to step 218.

In step 216, the MBIST scheduler module 30 transmits a fail signal to the ATE 16. In step 218, the MBIST scheduler module 30 transmits a pass signal to the ATE 16. In step 220, the MBIST scheduler module 30 determines whether another memory self-test algorithm has been scheduled. If the MBIST schedule module 30 determines that another memory self-test algorithm has been scheduled, the method 200 returns to step 206. If the MBIST scheduler module 30 determines that another memory self-test algorithm has not been scheduled, the method 200 proceeds to step 222. The method 200 ends in step 222.

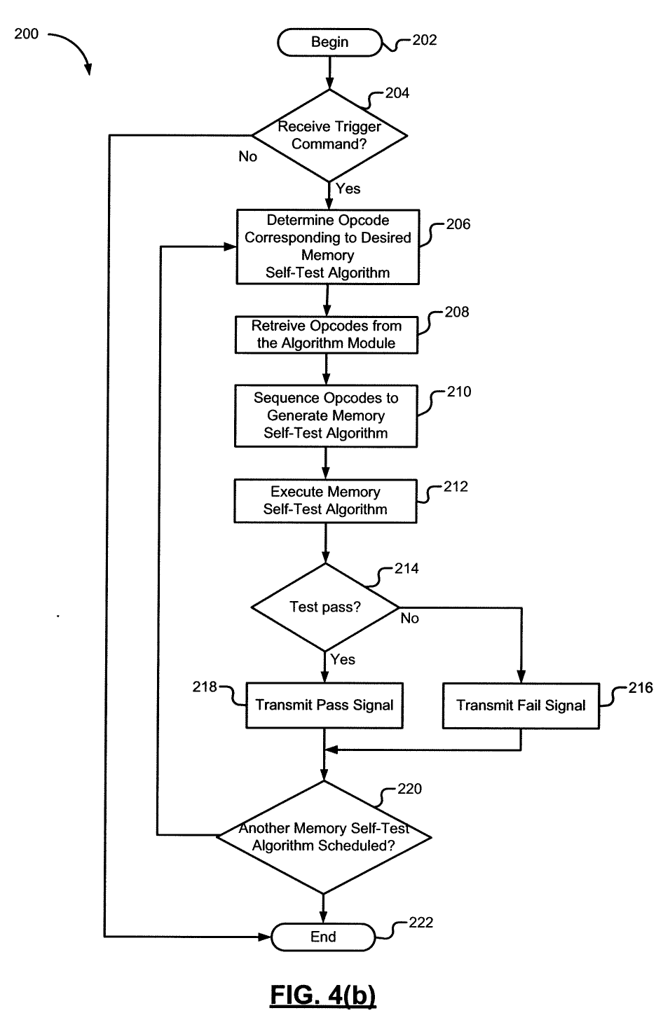

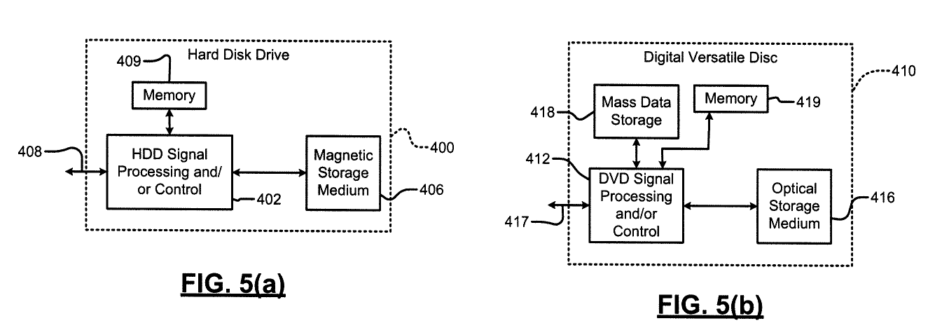

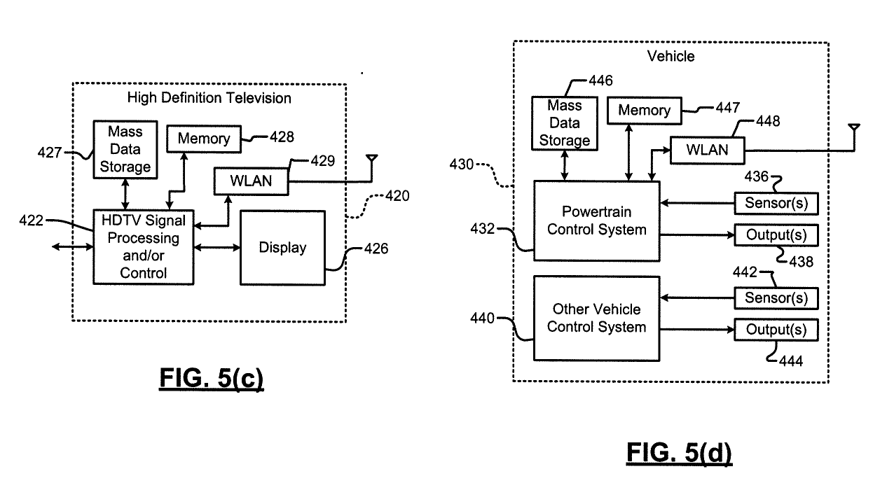

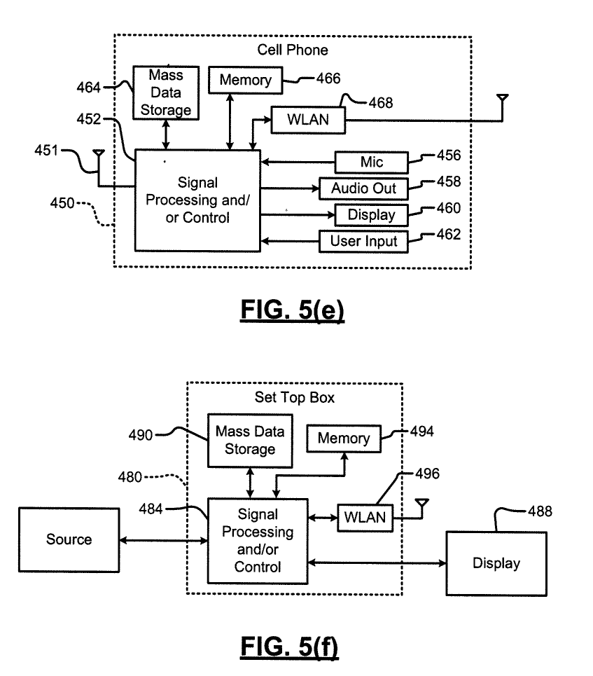

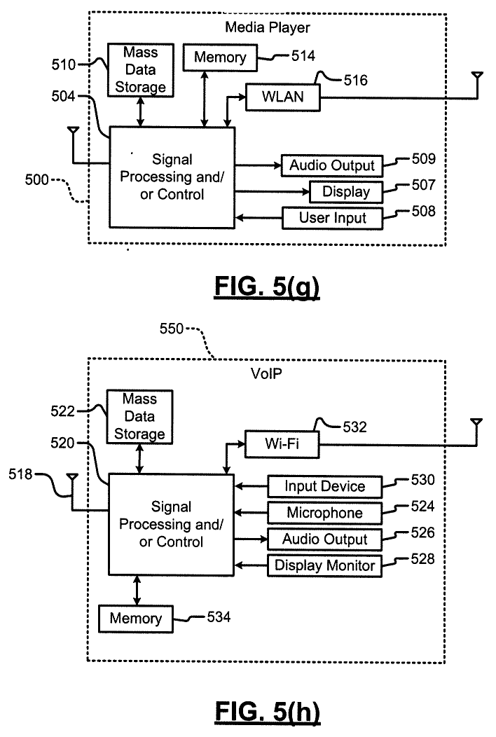

Referring now to FIGS. 5(a) to 5(h), various examples of devices in which embodiments of the present invention may be implemented are shown. Referring to FIG. 5(a), the present invention may be embodied in a hard disk drive (HDD) 400. HDD 400 may communicate with a host device (not shown) such as a computer, mobile computing devices such as personal digital assistants, cellular phones, media or MP3 players and the like, and/or other devices via one or more wired or wireless communication links 408.

The present invention may be implemented with either or both signal processing and/or control circuits, which are generally identified in FIG. 5(a) at 402. In some implementations, the signal processing and/or control circuit 402 and/or other circuits (not shown) in the HDD 400 may process data, perform coding and/or encryption, perform calculations, and/or format data that is output to and/or received from a magnetic storage medium 406. HDD 400 may be connected to memory 409, such as random access memory (RAM), a low latency nonvolatile memory such as flash memory, read only memory (ROM) and/or other suitable electronic data storage. Memory 409 may implement an embodiment of the BIST system of the present disclosure.

Referring now to FIG. 5(b), the present invention may be implemented in a digital versatile disc (DVD) drive 410. The present invention may be implemented in either or both signal processing and/or control circuits, which are generally identified in FIG. 5(b) at 412, and/or mass data storage 418 of DVD drive 410. Signal processing and/or control circuit 412 and/or other circuits (not shown) in DVD drive 410 may process data, perform coding and/or encryption, perform calculations, and/or format data that is read from and/or data written to an optical storage medium 416. In some implementations, signal processing and/or control circuit 412 and/or other circuits (not shown) in DVD drive 410 can also perform other functions such as encoding and/or decoding and/or any other signal processing functions associated with a DVD drive.

DVD drive 410 may communicate with a device (not shown) such as a computer, television or other device via one or more wired or wireless communication links 417. DVD drive 410 may communicate with mass data storage 418 that stores data in a nonvolatile manner. Mass data storage 418 may include a HDD such as that shown in FIG. 5(a). The HDD may be a mini HDD that includes one or more platters having a diameter that is smaller than approximately 1.8″ DVD drive 410 may be connected to memory 419, such as RAM, ROM, low latency nonvolatile memory such as flash memory, and/or other suitable electronic data storage. Memory 419 may implement an embodiment of the BIST system of the present disclosure.

Referring now to FIG. 5(c) the present invention may be embodied in a high definition television (HDTV) 420. The present invention may be implemented in either or both signal processing and/or control circuits, which are generally identified in FIG. 5(c) at 422, a WLAN interface 429 and/or mass data storage 427 of the HDTV 420. HDTV 420 may receive HDTV input signals in either a wired or wireless format via one or more wired or wireless communication links 424 and generate HDTV output signals for a display 426. In some implementations, signal processing circuit and/or control circuit 422 and/or other circuits (not shown) of HDTV 420 may process data, perform coding and/or encryption, perform calculations, format data and/or perform any other type of HDTV processing that may be required.

HDTV 420 may communicate with mass data storage 427 that stores data in a nonvolatile manner such as optical and/or magnetic storage devices. At least one HDD may have the configuration shown in either FIG. 5(a) and/or at least one DVD may have the configuration shown in FIG. 5(b). The HDD may be a mini HDD that includes one or more platters having a diameter that is smaller than approximately 1.8″ HDTV 420 may be connected to memory 428 such as RAM, ROM, low latency nonvolatile memory such as flash memory and/or other suitable electronic data storage. Memory 428 may implement an embodiment of the BIST system of the present disclosure. HDTV 420 also may support connections with a WLAN via a WLAN network interface 429.

Referring now to FIG. 5(d), the present invention may be implemented in a control system of a vehicle 430, a WLAN interface 448 and/or mass data storage 446 of the vehicle control system. In some implementations, the present invention is implemented in a power-train control system 432 that receives inputs from one or more sensors 436 such as temperature sensors, pressure sensors, rotational sensors, airflow sensors and/or any other suitable sensors and/or that generates one or more output control signals such as engine operating parameters, transmission operating parameters, and/or other control signals at one or more output(s) 438.

The present invention may also be embodied in other control systems 440 of vehicle 430. Control system 440 may likewise receive signals from input sensors 442 and/or output control signals to one or more output(s) 444. In some implementations, control system 440 may be part of an anti-lock braking system (ABS), a navigation system, a telematics system, a vehicle telematics system, a lane departure system, an adaptive cruise control system, a vehicle entertainment system such as a stereo, DVD, compact disc and the like. Still other implementations are contemplated.

Powertrain control system 432 may communicate with mass data storage 446 that stores data in a nonvolatile manner. Mass data storage 446 may include optical and/or magnetic storage devices, for example HDDs and/or DVDs. At least one HDD may have the configuration shown in FIG. 5(a) and/or at least one DVD may have the configuration shown in FIG. 5(b). The HDD may be a mini HDD that includes one or more platters having a diameter that is smaller than approximately 1.8″ Powertrain control system 432 may be connected to memory 447 such as RAM, ROM, low latency nonvolatile memory such as flash memory and/or other suitable electronic data storage. Memory 447 may implement an embodiment of the BIST system of the present disclosure. Powertrain control system 432 also may support connections with a WLAN via a WLAN network interface 448. The control system 440 may also include mass data storage, memory and/or a WLAN interface (all not shown).

Referring now to FIG. 5(e), the present invention may be embodied in a cellular phone 450 that may include a cellular antenna 451. The present invention may be implemented in either or both signal processing and/or control circuits, which are generally identified in FIG. 5(e) at 452, a WLAN interface and/or mass data storage of the cellular phone 450. In some implementations, cellular phone 450 includes a microphone 456, an audio output 458 such as a speaker and/or audio output jack, a display 460 and/or an input device 462 such as a keypad, pointing device, voice actuation and/or other input device. Signal processing and/or control circuits 452 and/or other circuits (not shown) in cellular phone 450 may process data, perform coding and/or encryption, perform calculations, format data and/or perform other cellular phone functions.

Cellular phone 450 may communicate with mass data storage 464 that stores data in a nonvolatile manner such as optical and/or magnetic storage devices, for example HDDs and/or DVDs. At least one HDD may have a configuration shown in FIG. 5(a) and/or at least one DVD may have the configuration shown in FIG. 5(b). The HDD may be a mini HDD that includes one or more platters having a diameter that is smaller than approximately 1.8″ Cellular phone 450 may be connected to memory 466 such as RAM, ROM, low latency nonvolatile memory such as flash memory and/or other suitable electronic data storage. Memory 466 may implement an embodiment of the BIST system of the present disclosure. Cellular phone 450 also may support connections with a WLAN via a WLAN network interface 468.

Referring now to FIG. 5(f), the present invention may be embodied in a set top box 480. The present invention may be implemented in either or both signal processing and/or control circuits, which are generally identified in FIG. 5(f) at 484, a WLAN interface and/or mass data storage of the set top box 480. Set top box 480 receives signals from a source such as a broadband source and outputs standard and/or high definition audio/video signals suitable for a display 488 such as a television and/or monitor and/or other video and/or audio output devices. Signal processing and/or control circuits 484 and/or other circuits (not shown) of the set top box 480 may process data, perform coding and/or encryption, perform calculations, format data and/or perform any other set top box function.

Set top box 480 may communicate with mass data storage 490 that stores data in a nonvolatile manner. Mass data storage 490 may include optical and/or magnetic storage devices, for example HDDs and/or DVDs. At least one HDD may have a configuration shown in FIG. 5(a) and/or at least one DVD may have the configuration shown in FIG. 5(b). The HDD may be a mini HDD that includes one or more platters having a diameter that is smaller than approximately 1.8″ Set top box 480 may be connected to memory 494 such as RAM, ROM, low latency nonvolatile memory such as flash memory and/or other suitable electronic data storage. Memory 494 may implement an embodiment of the BIST system of the present disclosure. Set top box 480 also may support connections with a WLAN via a WLAN network interface 496.

Referring now to FIG. 5(g), the present invention may be embodied in a media player 500. The present invention may be implemented in either or both signal processing and/or control circuits, which are generally identified in FIG. 5(g) at 504, a WLAN interface and/or mass data storage of the media player 500. In some implementations, media player 500 includes a display 507 and/or a user input 508 such as a keypad, touchpad and the like. In some implementations, media player 500 may employ a graphical user interface (GUI) that typically employs menus, drop down menus, icons and/or a point-and-click interface via display 507 and/or user input 508. Media player 500 further includes an audio output 509 such as a speaker and/or audio output jack. Signal processing and/or control circuits 504 and/or other circuits (not shown) of media player 500 may process data, perform coding and/or encryption, perform calculations, format data and/or perform any other media player function.

Media player 500 may communicate with mass data storage 510 that stores data such as compressed audio and/or video content in a nonvolatile manner. In some implementations, the compressed audio files include files that are compliant with MP3 format or other suitable compressed audio and/or video formats. The mass data storage 510 may include optical and/or magnetic storage devices, for example HDDs and/or DVDs. At least one HDD may have a configuration shown in FIG. 5(a) and/or at least one DVD may have the configuration shown in FIG. 5(b). The HDD may be a mini HDD that includes one or more platters having a diameter that is smaller than approximately 1.8″.

Media player 500 may be connected to memory 514 such as RAM, ROM, low latency nonvolatile memory such as flash memory and/or other suitable electronic data storage. Memory 514 may implement an embodiment of the BIST system of the present disclosure. Media player 500 also may support connections with a WLAN via a WLAN network interface 516. Still other implementations in addition to those described above are contemplated.

Referring to FIG. 5(h), the present invention may be embodied in a Voice over Internet Protocol (VoIP) phone 550 that may include an antenna 518. The present invention may be implemented in either or both signal processing and/or control circuits, which are generally identified in FIG. 5(h) at 520, a wireless interface and/or mass data storage of the VoIP phone 550. In some implementations, VoIP phone 550 includes, in part, a microphone 524, an audio output 526 such as a speaker and/or audio output jack, a display monitor 528, an input device 530 such as a keypad, pointing device, voice actuation and/or other input devices, and a Wi-Fi communication module 532. Signal processing and/or control circuits 520 and/or other circuits (not shown) in VoIP phone 550 may process data, perform coding and/or encryption, perform calculations, format data and/or perform other VoIP phone functions.

VoIP phone 550 may communicate with mass data storage 522 that stores data in a nonvolatile manner such as optical and/or magnetic storage devices, for example HDDs and/or DVDs. At least one HDD may have a configuration shown in FIG. 5(a) and/or at least one DVD may have the configuration shown in FIG. 5(b). The HDD may be a mini HDD that includes one or more platters having a diameter that is smaller than approximately 1.8″ VoIP phone 550 may be connected to memory 534, which may be a RAM, ROM, low latency nonvolatile memory such as flash memory and/or other suitable electronic data storage. Memory 534 may implement an embodiment of the BIST system of the present disclosure. VoIP phone 550 is conFIG.d to establish communications link with a VoIP network (not shown) via Wi-Fi communication module 532.

All of the discussion above, regardless of the particular implementation being described, is exemplary in nature, rather than limiting. Although specific components of the print system are described, methods, systems, and articles of manufacture consistent with the print system may include additional or different components. For example, components of the print system may be implemented by one or more of: control logic, hardware, a microprocessor, microcontroller, application specific integrated circuit (ASIC), discrete logic, or a combination of circuits and/or logic. Further, although selected aspects, features, or components of the implementations are depicted as hardware or software, all or part of the systems and methods consistent with the print system may be stored on, distributed across, or read from machine-readable media, for example, secondary storage devices such as hard disks, floppy disks, and CD-ROMs; a signal received from a network; or other forms of ROM or RAM either currently known or later developed. Any act or combination of acts may be stored as instructions in computer readable storage medium. Memories may be DRAM, SRAM, Flash or any other type of memory. Programs may be parts of a single program, separate programs, or distributed across several memories and processors.

The processing capability of the system may be distributed among multiple system components, such as among multiple processors and memories, optionally including multiple distributed processing systems. Parameters, databases, and other data structures may be separately stored and managed, may be incorporated into a single memory or database, may be logically and physically organized in many different ways, and may implemented in many ways, including data structures such as linked lists, hash tables, or implicit storage mechanisms. Programs and rule sets may be parts of a single program or rule set, separate programs or rule sets, or distributed across several memories and processors.

It is intended that the foregoing detailed description be understood as an illustration of selected forms that the invention can take and not as a definition of the invention. It is only the following claims, including all equivalents, that are intended to define the scope of this invention.

What is claimed is:

1. A built-in-self-test (BIST) system for testing a memory, comprising:
a scheduler module that generates a first test algorithm based on a set of modular operational codes, wherein each operational code defines a test operation to be performed by the first test algorithm on the memory; and
an execution module that applies the test algorithm to the memory.

2. The system of claim 1 further comprising an external device that defines at least one of the set of operational codes to be performed by the first test algorithm and that defines a sequence of performing the set of operational codes.

3. The system of claim 1 wherein the set of operational codes is stored internal to a device that includes the memory.

4. The system of claim 1 wherein the scheduler module generates the first test algorithm when the BIST system receives a trigger command.

5. The system of claim 1 wherein the scheduler module retrieves the set of operational codes from an internal memory of the BIST system.

6. The system of claim 1 wherein the execution module applies the first test algorithm at an operating speed of the memory.

7. The system of claim 2 wherein the scheduler module generates a second test algorithm that is different from the first test algorithm when the external device modifies one of a composition of the set of operational codes and the sequence of the operational codes relative to the first algorithm.

8. The system of claim 1 wherein the scheduler module generates a second test algorithm when an external device transmits to the scheduler module another operational code that is different from the operational codes in the first test algorithm.

9. The system of claim 1 wherein the scheduler module receives the set of operational codes from an external device.

10. The system of claim 2 wherein the external device includes automated test equipment.

11. The system of claim 1 wherein the scheduler module transmits a pass signal when the test algorithm fails to generate an error and transmits a fail signal when the test algorithm generates an error.

12. The system of claim 1 wherein the memory includes memory external to the BIST system.

13. A built-in-self-test (BIST) method for testing a memory, the method comprising:
generating a first test algorithm based on a set of operational codes, wherein each operational code defines a test operation to be performed by the test algorithm on the memory; and
applying the test algorithm to the memory.

14. The method of claim 13 further comprising communicating with an external device that defines at least one of the set of operational codes to be performed by the first test algorithm and that defines a sequence of performing the set of operational codes.

15. The method of claim 13 wherein the set of operational codes is stored internal to a device that includes the memory.

16. The method of claim 13 further comprising generating the first test algorithm based on receiving a trigger command.

17. The method of claim 13 further comprising retrieving the set of operational codes from an internal memory.

18. The method of claim 13 further comprising applying the first test algorithm at an operating speed of the memory.

19. The method of claim 14 further comprising generating a second test algorithm that is different from the first test algorithm by modifying one of a composition of the set of operational codes and the sequence of the operational codes relative to the first test algorithm.

20. The method of claim 13 further comprising generating a second test algorithm based on receiving another operational code that is different from the operational codes in the first test algorithm.

21. The method of claim 13 further comprising receiving the set of operational codes from an external device.

22. The method of claim 14 wherein the external device includes automated test equipment.

23. The method of claim 13 further comprising transmitting a pass signal when the test algorithm fails to generate an error and transmitting a fail signal when the test algorithm generates an error.

24. A built-in-self-test (BIST) system for testing a memory, comprising:
scheduler means for generating a first test algorithm based on a set of modular operational codes, wherein each operational code defines a test operation to be performed by the first test algorithm on the memory; and
execution means for applying the test algorithm to the memory.

25. The system of claim 24 further comprising an external device that defines at least one of the set of operational codes to be performed by the first test algorithm and that defines a sequence of performing the set of operational codes.
